(19) United States
(12) Patent Application Publication
(10) Pub. No.: US 2011/0064645 A1
(43) Pub. Date: Mar. 17, 2011

(54) CARBON NANOTUBE AND METHOD FOR PRODUCING THE SAME

(75) Inventors: Jyh-Ming TING, Tainan City (TW); Wen-Chen Lin, Taipei County (TW)

(73) Assignee: National Cheng Kung University, Tainan City (TW)

(21) Appl. No.: 12/635,957

(22) Filed: Dec. 11, 2009

(30) Foreign Application Priority Data
Sep. 14, 2009 (TW) 98130882

(51) Int. Cl. D01F 9/12; B05D 3/02; B05D 3/10; C23C 16/26; C23C 16/44; C23C 14/34; C25D 5/48

(52) U.S. Cl. 423/447.2; 427/372.2; 216/37; 427/383.1; 427/249.1; 204/192.1; 205/194; 977/742; 977/842; 977/843

(57) ABSTRACT

The present invention provides a method for producing carbon nanotubes comprising (a) providing a substrate; (b) coating a catalyst layer on said substrate; (e) heating the substrate from step (b); (d) continuously supplying a carbon source to grow carbon nanotubes; (e) interrupting the supplement of the carbon source and supplying an oxidizing gas; and (f) resupplying the carbon source to make the carbon nanotubes obtained from step (d) to re-grow at a higher growth rate. The present invention also provides carbon nanotubes fabricated by the above-mentioned method. The carbon nanotubes have extremely excellent field emission properties.

### BACKGROUND OF THE INVENTION

1. Field of the Invention

The present invention relates to carbon nanotubes and a method for producing the same, and more specifically, to a method for producing carbon nanotubes, which has faster growing rate in re-growing stages and carbon nanotubes with excellent field emission property (such as low turn-on field), which are produced according to the aforesaid method.

2. Description of the Related Art

Carbon nanotubes (CNTs) are nanotubular material with specific physical and chemical properties and existed in the form of pure carbon. Carbon nanotubes also have some new properties such as: very high electrical conductivity, extremely high modulus and strength, light weight, high surface area, and great thermal conductivity, and thus have several new applications in, such as, electronics, photoelectronics, machinery, materials, and biochemistry, and chemical engineering.

Conventional methods for producing carbon nanotubes mainly include arc-discharge, chemical vapor deposition (CVD), pulsed laser deposition, plasma enhanced CVD, microwave plasma CVD and laser ablation, wherein all of them involve single-use and/or continuous supply of catalysts to grow carbon nanotubes.

However, the costs of the carbon nanotubes produced by aforesaid methods are high. Hence, their applications are restricted. In order to achieve the applications of carbon nanotubes, people are performing intensive researches focusing on the growth mechanisms and the growth methods, hoping to find out solutions to lower the production cost of carbon nanotubes. As such, the great physical and chemical properties of carbon nanotubes can be applied to information electronics, medical care, novel material, energy conservation, biotechnology, green sustainable engineering and various areas to open up a new future.

### SUMMARY OF THE INVENTION

In view of this, an object of the present invention is to provide a method different from traditional methods for producing carbon nanotubes. In said method, the growth of carbon nanotubes is interrupted during the growth thereof, resulting in re-activation of poisoned catalyst, which then further accelerates the growth of carbon nanotubes. Also, carbon nanotubes which are produced by the stepped growth have excellent field emission properties.

Another object of the present invention is to provide carbon nanotubes which are produced according to said method. The carbon nanotubes have extremely high aspect ratios, leading to excellent field emission properties.

To achieve above objects, the present invention provides a method for producing carbon nanotubes, which comprises the steps of: (a) providing a substrate; (b) coating a catalyst layer on said substrate; (c) heating the substrate with said catalyst layer; (d) continuously supplying a carbon source to grow carbon nanotubes; (e) interrupting the supplement of the carbon source and supplying an oxidizing gas; and (f) resupplying the carbon source to make the carbon nanotubes obtained from step (d) to re-grow.

Preferably, said method further comprises an etching step between said step (b) and said step (c).

Preferably, said carbon source of said step (d) is continuously supplied for 1˜30 minute; said oxidizing gas of said step (e) is continuously supplied for 30 second to 3 minute.

Preferably, said method further repeats said steps (e) to (f) after said step (f).

The present invention also provides a method for producing carbon nanotubes, which comprises the steps of: (a) providing a substrate; (b) coating a catalyst layer on said substrate; (c) heating the substrate with said catalyst layer; and (d) continuously supplying a carbon source to grow carbon nanotubes; wherein said method characterized by: supplying an oxidizing gas and interrupting the supplement of said carbon source at the same time during the period of continuously supplying said carbon source; and stopping the supplement of said oxidizing gas and resupplying said carbon source.

Preferably, said substrate is a silicon substrate, a glass substrate, or metallic substrates.

Preferably, said catalyst layer is obtained by sputter deposition, electro-plating, or wet chemistry methods.

Preferably, said catalyst layer is iron, iron-silicon alloys, or iron-silicon alloy containing an aluminum underlayer.

Preferably, said method further comprises an etching step before said continuously supplying a carbon source.

Preferably, said substrate in said step (c) is heated to 370˜410° C.

Preferably, said carbon source is methane, ethane, propane, benzene, mixture thereof or combination thereof with an equilibrium gas and said equilibrium gas is hydrogen, oxygen, nitrogen, ammonia or mixture thereof.

Preferably, said oxidizing gas is oxygen, air, or gas containing the same.

Yet the present invention provides carbon nanotubes, which are produced according to said methods.

To sum up, the present invention takes advantage of a newly stepped growth process to grow carbon nanotubes. The process is fast and the temperature needed is low. The area density of carbon nanotubes produced by said process is high and growth rate is increased and thereof very fast. Therefore, the cost thereof is lowered. Moreover, re-activation of catalyst also benefits to lower production cost. Further, as the process of the present invention is conducted under low temperatures, the resulting carbon nanotubes are more suitably applied in low-melting point substrates.

### BRIEF DESCRIPTION OF THE DRAWINGS

FIGS. 1A-1C illustrate the flow chart of the growth of carbon nanotubes disclosed in the present invention.

FIG. 2A is a SEM image of the carbon nanotubes of the comparative example 2 of the present invention.

FIG. 2B is a SEM image of the carbon nanotubes of the example 3 of the present invention.

FIG. 2C is a SEM image of the carbon nanotubes of the comparative example 3 of the present invention.

FIG. 2D is a SEM image of the carbon nanotubes of the example 1 of the present invention.

FIG. 3A is a TEM image showing the root of the carbon nanotubes in accordance with the example 1 of the present invention during the interruption.

FIG. 3B illustrates an energy dispersive X-ray image (EDX) of the circle location in FIG. 3A.

FIG. 4 shows the comparison between the lengths of carbon nanotubes obtained by continuous growth process and those obtained by stepped growth process during different stages.

FIG. 5 illustrates a TEM image of an interface line of the carbon nanotubes of present invention, wherein the interface line was pointed out by the arrow.

FIG. 6A illustrates an I-E curve of the carbon nanotubes of the comparative example 2.

FIG. 6B illustrates an I-E curve of the carbon nanotubes of the example 1.

### DETAILED DESCRIPTION OF THE INVENTION

The present invention relates to a novel method for production of carbon nanotubes, wherein said method employs a stepped growth process to produce carbon nanotubes. Carbon nanotubes produced according to the method are more suitably applied in components of field emission flat panel displays, photoelectronic materials and electrochemical devices (ex. capacitor), but applications thereof do not be limited.

The method of present invention for producing carbon nanotubes comprises: (a) providing a substrate, wherein the substrate includes but not limited to a silicon substrate, a glass substrate, or metallic substrates; (b) coating a catalyst layer on said substrate, wherein said catalyst layer is obtained by sputter deposition, electro-plating, or wet chemistry methods, but not limited to them; (c) heating the substrate with said catalyst layer; (d) continuously supplying a carbon source to grow carbon nanotubes, wherein the carbon source includes but not limited to methane, ethane, propane, benzene, mixture thereof or combination thereof with an equilibrium gas; (e) interrupting the supplement of the carbon source and supplying an oxidizing gas, wherein said oxidizing gas comprises but not limited to oxygen, air, or gas containing the same; and (f) resupplying the carbon source to make the carbon nanotubes obtained from step (d) to re-grow.

The carbon source used in the present invention is a mixture gas of methane and an equilibrium gas, wherein the equilibrium gas is hydrogen, and the ratio thereof is 4/9. However, it should be appreciated that the composition and ratio of the carbon source can be changed as required, for instance, said equilibrium gas includes but not limited to hydrogen, oxygen, nitrogen, ammonia or mixture thereof; and the ratio of methane to said equilibrium gas may be but not limited to 1/9, 2/9, 3/9 or 4/9.

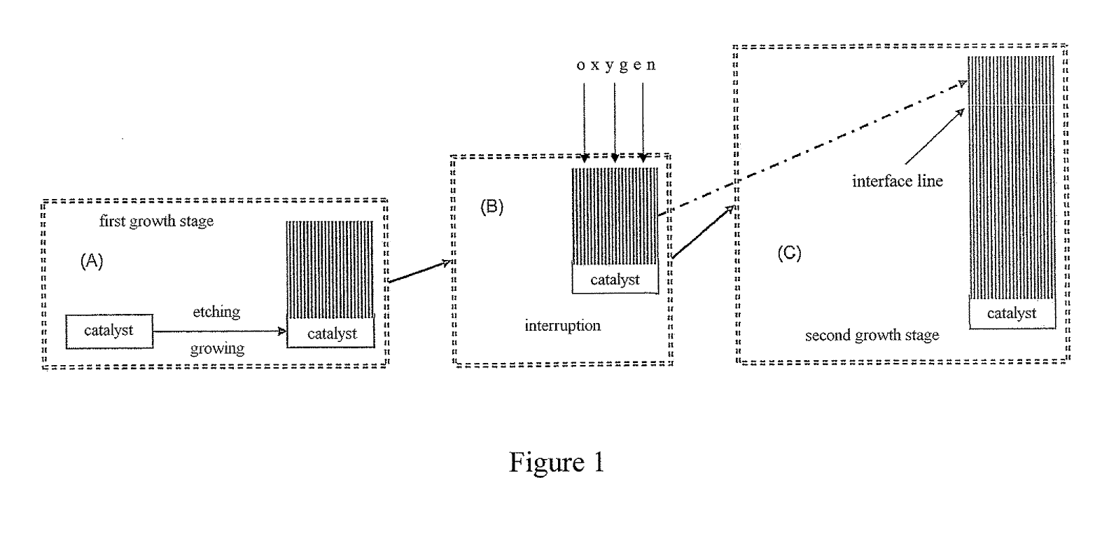

Please refer to FIG. 1A to FIG. 1C, showing the flow chat of the carbon nanotube growth of the present invention. As shown in FIG. 1, the growth of carbon nanotubes of present invention in the first stage is the same as the growth of conventional carbon nanotubes. Then, the carbon source is terminated and an oxidizing gas is supplied as shown in FIG. 1B. The growth of the carbon nanotubes of present invention is conducted in a microwave plasma-enhanced chemical vapor deposition (MPCVD) system. The requirement of interrupting supplement of carbon source and supplying an oxidizing gas can be achieved at the same time by simple turning off and turning on the processing gas valves and oxygen (or air) inlet valve, respectively. It is appreciated that the requirement can be achieved by other ways which would not be mentioned here. The poisoned catalyst (that is, catalyst which has been reacted) will be oxidized as the carbon nanotubes are taken out from said MPCVD system. After oxidation of said catalyst, substrate having carbon nanotubes remaining in the MPCVD system are exposed to second growth stage. In said second growth stage, the carbon nanotubes can re-grow at a faster rate as shown in FIG. 1C. Besides, in the process according to the present invention, the catalyst layer is preferably processed by an etching step prior to the first growth stage of carbon nanotubes. The etching gas used in said etching step includes but not limited to hydrogen, oxygen, nitrogen, ammonia or mixture thereof.

The following examples are provided for understanding the advantages and technical features of present invention, but these examples are not intended to limit the scope of present invention. Any amendments and modifications can be made by those skilled in the art without departing the spirit and scope of the present invention. Therefore, the scope of the present invention is defined by the appended claims.

### Example

### Production of a Carbon Nanotube

An aluminum layer was deposited on a silicon substrate by sputter deposition. Thickness of said aluminum layer was adjusted by controlling the time of the sputtering and was fall in the range of 2˜8 nm. The thickness of said aluminum layer used in the examples was 4 nm.

Then, a 24 nm of iron-silicon alloy film was co-sputtered on said aluminum layer to obtain a catalyst layer of iron-silicon alloy with an aluminum underlayer, wherein the composition ratio of the iron-silicon alloy film was defined according to the silicon target power provided during sputtering. In these examples, the amount of silicon of iron-silicon alloy is 23%.

After the aforesaid procedure, the silicon substrate having catalyst layer was put into a MPCVD system for the growth of carbon nanotubes. The operation condition of said MPCVD system was: microwave power of 500 W; and working pressure of 20 Torr. The catalyst layer was etched by hydrogen in the system, wherein the condition for etching was: microwave power of 500 W; and hydrogen pressure of 20 Torr.

Then, the temperature of the MPCVD system was raised up to 390±20° C. by microwave plasma, and a mixture of methane and hydrogen (4:9) was introduced as a carbon source. Carbon nanotubes grew for X minutes (that is the growth time of first growth stage, wherein X of each of examples and comparative examples was shown in the following table 1) to obtain a first substrate having carbon nanotubes.

After that, the processing gas valve was turned off (that is, the supplement of carbon source was terminated) and air was introduced into the MPCVD system to contact with the first substrate having carbon nanotubes for two minutes. Then, air valve was turned off and the processing gas (carbon source of mixture of methane and hydrogen in the ratio of 4:9) was introduced into the MPCVD system again to re-grow the carbon nanotubes. The carbon nanotubes grew for Y minutes (that is the growth time of second growth stage, wherein Y of each of examples and comparative examples was shown in the following table 1) to obtain a second substrate having carbon nanotubes.

Then, said second substrate having carbon nanotubes was subjected to the aforesaid procedures of contacting with air for 2 minutes and re-growing for Z minutes (that is the growth time of third growing stage, wherein Z of each of examples and comparative examples was shown in the following table 1) to obtain a third substrate having carbon nanotubes.

TABLE 1
X, Y and Z of each of examples and comparative examples

| | X | Y | Z | Given name during process |
|---|---|---|---|---|
| Example 1 | 5 | 10 | 0 | G5G10 |
| Example 2 | 5 | 5 | 5 | 3G5 |
| Example 3 | 10 | 5 | 0 | G10G5 |
| Example 4 | 5 | 5 | 0 | 2G5 |
| Comparative | 15 | 0 | 0 | G15 |
| example 1 | | | | |
| Comparative | 10 | 0 | 0 | G10 |
| example 2 | | | | |
| Comparative | 5 | 0 | 0 | G5 |
| example 3 | | | | |

1. G5G10 represented said carbon nanotubes grew by two growth stages, and time of first growth stage was 5 minutes; time of second growth stage was 10 mnuites, wherein G represented growth; 5 and 10 represented 5 minutes and 10 minutes respectively.
2. 3G5 represented said carbon nanotubes grew by three growth stages and time of first, second and third growth stage was 5 minutes.
3. 2G5 represented said carbon nanotubes grew by two growth stages, and time of first and second growth stage was 5 minutes.

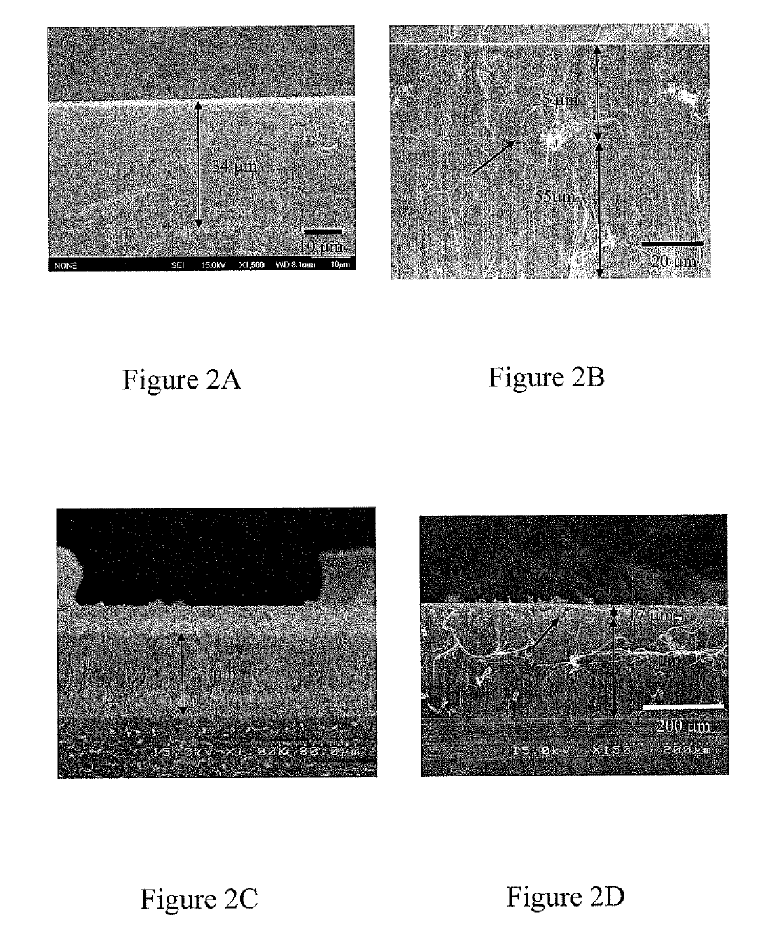

FIGS. 2A-2D were SEM images of carbon nanotubes of aforesaid comparative example 2, example 3, example 1 and comparative example 3, respectively. FIG. 2A displayed that the method of comparative example 2 could only produce carbon nanotubes with a length of 34 μm due to catalyst poisoning and hydrogen-rich condition inside said system, which shorten the carbon nanotubes. By contrast, carbon nanotubes with a length of 80 μm could be obtained by using the stepped growth method of present invention (G10G5). Moreover, as shown in FIG. 2B, an interface line could be seen on the carbon nanotubes (which was pointed out by the arrow in FIG. 2B). We also found that the method of present invention not only increased the length of carbon nanotubes but also increased their growth rate during the re-growth. FIG. 2C displayed that the process of continuous growth for 5 minutes could only produce carbon nanotubes with a length of 25 μm. FIG. 2D showed that G10G5 process could produce carbon nanotubes with a length of 270 μm and a clear interface line (which was pointed out by the arrow) could be seen thereon. The length of the carbon nanotubes above the interface line was 17 μm, which was shorter than that of aforesaid carbon nanotubes growing for 5 minutes continuously (25 μm, shown in FIG. 2C). However, the growth length of the carbon nanotubes during second growth stage was 253 μm, which was much longer than the length of the carbon nanotubes of comparative example 2, which continuously grew for 10 minutes (34 μm as shown in FIG. 2A).

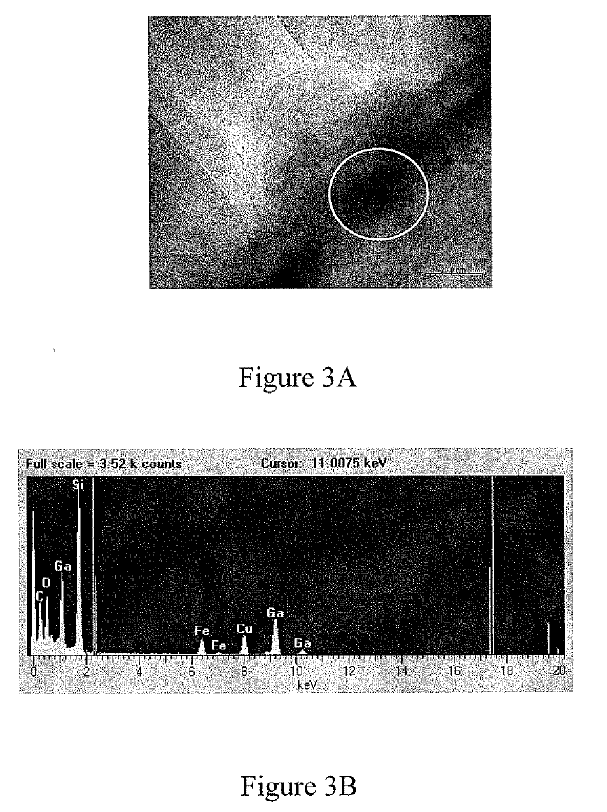

FIG. 3A was a TEM image displaying the roots of carbon nanotubes in accordance with the example 1 of present invention during the interruption. FIG. 3B was the energy dispersive X-ray image (EDX) of the circle location in FIG. 3A. According to FIG. 3A and FIG. 3B, Fe in the catalyst layer was oxidized to form amorphous Fe₂O₃, which demonstrated that the poisoned catalyst had been re-activated, carbon in the saturated Fe has been removed, leaving Fe exposed to oxidation to form Fe₂O₃. The C, Ga and Cu in FIG. 3B were from carbon nanotubes or sample preparation by using focused ion beam.

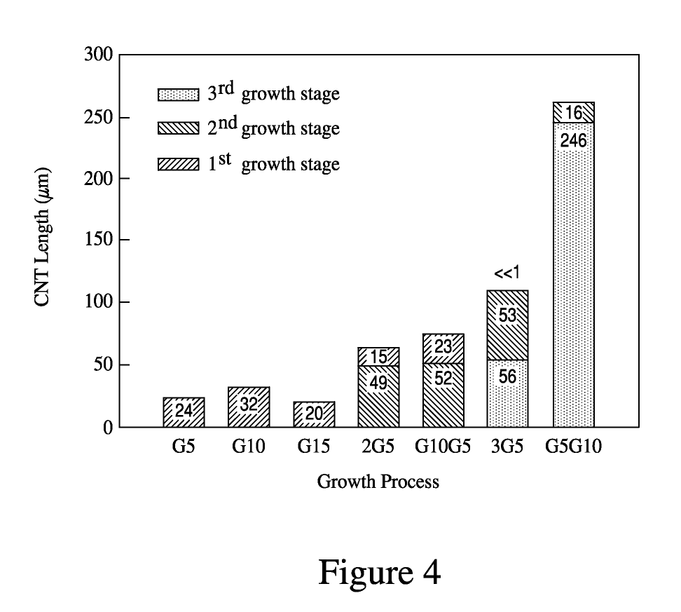

FIG. 4 showed the comparison between the length of carbon nanotubes obtained by continuous growth process and those obtained by stepped growth process during different stages, wherein said continuous growth process included carbon nanotubes continuously growing for 5 minutes (G5), 10 minutes (G10) and 15 minutes (G15); said stepped growth process included carbon nanotubes growing for two 5 minutes growth stages (2G5), one 10 minutes growth stage and one 5 minutes stage (G10G5), three 5 minutes growth stages (3G5) and one 5 minutes stage and one 10 minutes growth stage (G5G10). According to the result shown in FIG. 4, the lengths of carbon nanotubes obtained by said continuous growth process were all shorter than those obtained by said stepped growth process. In the 2G5 process, the length of carbon nanotubes of first 5 minutes growth stage was shorter than that of continuously growing for 5 minutes; that is 15 μm v.s. 24 μm. However, the length of carbon nanotubes of second 5 minutes growth stage was longer than that of continuously growing for 5 minutes; that is 49 μm v.s. 24 μm. The result demonstrated that the growth rate of carbon nanotubes were raised up to 104% during said second stage. Similar acceleration in growth rate also showed in the second stage and third stage of 3G5 process; that is the growth rate was raised up to 121% (from 24 μm to 53 μm) in second stage and 133% (from 24 μm to 56 μm) in third stage. Besides, although both of G10 and 2G5 processes had the total growth time of 10 min, it is quite obvious that the length of carbon nanotubes produced by said 2G5 process was longer. Also, all of G15, G10G5, 3G5 and G5G10 processes had the total growth time of 15 min, but the length of carbon nanotubes produced by stepped growth process was longer. Moreover, please refer to the result of G5G10 process shown in FIG. 4, the carbon nanotube grew a length of 246 μm in the second 10 minute growth stage, which was an increases level of 669% comparing with the carbon nanotubes produced by G10 process (32 μm).

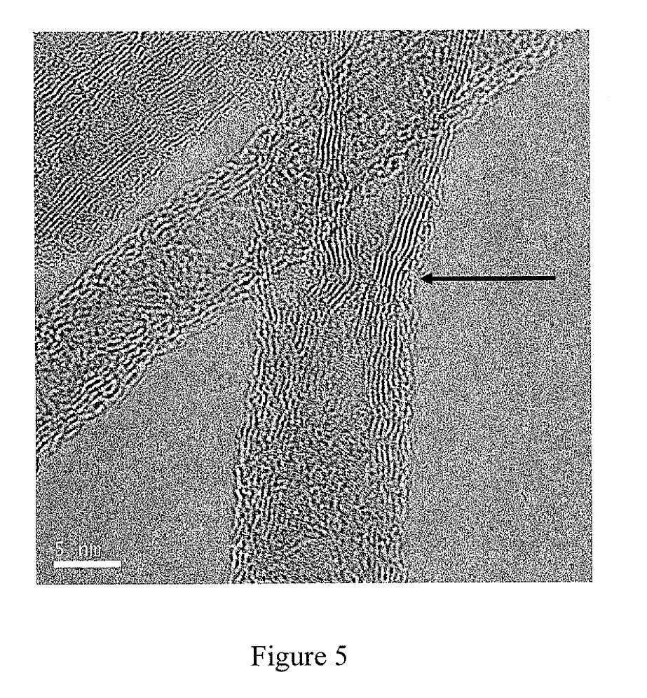

FIG. 5 was a TEM image of an interface line of the carbon nanotubes of present invention, wherein the interface line was pointed by the arrow. Although said interface line of stepped growth could be observed in SEM image, FIG. 5 showed that the concentric ring was continuous at the interface, which meant the structure thereof was continuous. However, the diameter narrowed at the junction.

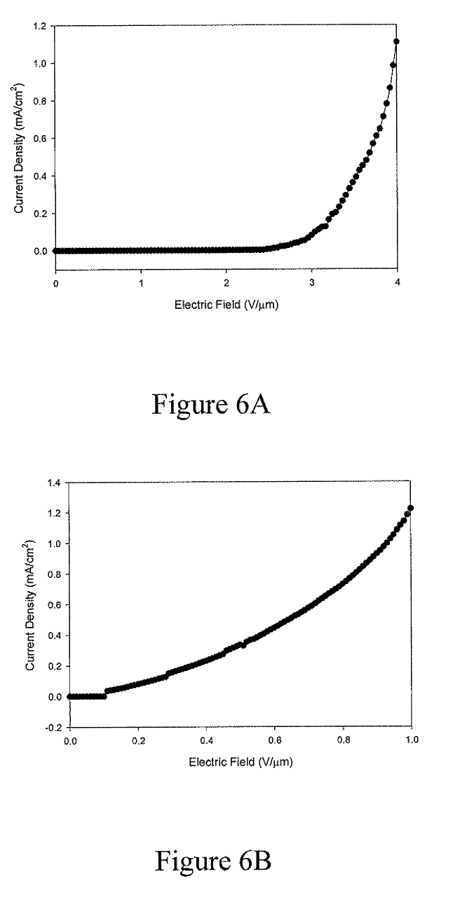

FIG. 6A and FIG. 6B were I-E curves of carbon nanotubes of comparative example 2 and example 1, respectively. The carbon nanotubes of comparative example 2 (G10) had an average length of 32 μm and average diameter of 9 nm, giving a high aspect ratio of 3,556. According to FIG. 6A which demonstrated an I-E curve of comparative example 2, the turn-on filed of carbon nanotubes produced by G10 process was 2.56 V/μm, and said carbon nanotubes had maximum current density of 1.11 mA/cm² at the turn-on field of 4 V/μm. Other carbon nanotubes produced by continuous growth processes had similar values (data not shown). FIG. 6B displayed an I-E curve of carbon nanotubes of example 1. The carbon nanotubes of example 1 (G5G10) had an average length of 182 μm and average diameter of 10 nm, giving an extremely high aspect ratio of 18,200. According to the result shown in FIG. 6B, the turn-on filed of carbon nanotubes of example 1 was 0.10 V/μm, and said carbon nanotubes had maximum current density of 1.22 mA/cm² at turn-on field of 1 V/μm. Said values were unchanged after performing 10-cyclic test. From the above, the carbon nanotube produced by the stepped growth process of present invention had extremely low turn-on field due to excellent aspect ratio thereof and remove of impurities thereon.

In view of this, the present invention taught to use an oxidizing gas to interrupt the continuous growth of carbon nanotubes during growing, thereby achieving the object of stepped growth. During aforesaid interruption, catalyst was re-activated by said oxidizing gas resulting in acceleration of carbon nanotubes growth. Also, carbon nanotubes produced by aforesaid process had excellent field emission property, extremely high aspect ratio and extremely low turn-on field which significantly increased future application thereof.

### Other Embodiments

The preferred embodiments of the present invention have been disclosed in the examples. All modifications and alterations without departing from the spirits of the invention and appended claims, including the other embodiments shall remain within the protected scope and claims of the invention.

The preferred embodiments of the present invention have been disclosed in the examples. However, the examples should not be construed as a limitation on the actual applicable scope of the invention, and as such, all modifications and alterations without departing from the spirits of the invention and appended claims, including the other embodiments shall remain within the protected scope and claims of the invention.

What is claimed is:

1. A method for producing carbon nanotubes, comprising steps of:
(a) providing a substrate;
(b) coating a catalyst layer on said substrate;
(c) heating the substrate with said catalyst layer;
(d) continuously supplying a carbon source to grow carbon nanotubes;
(e) interrupting the supplement of the carbon source and supplying an oxidizing gas; and
(f) resupplying the carbon source to make the carbon nanotubes obtained from step (d) to re-grow.

2. The method according to claim 1, wherein the substrate is a silicon substrate, a glass substrate, or metallic substrates.

3. The method according to claim 1, wherein the catalyst layer is obtained by sputter deposition, electro-plating, or wet chemistry methods.

4. The method according to claim 1, wherein the catalyst layer is made of iron, iron-silicon alloys, or an iron-silicon alloy containing an aluminum underlayer.

5. The method according to claim 1, wherein the method further comprises an etching step between said step (b) and said step (c).

6. The method according to claim 1, wherein the substrate in said step (e) is heated to 370˜410° C.

7. The method according to claim 1, wherein the carbon source is methane, ethane, propane, benzene, mixture thereof or combination thereof with an equilibrium gas.

8. The method according to claim 7, wherein the equilibrium gas is hydrogen, oxygen, nitrogen, ammonia or mixture thereof.

9. The method according to claim 1, wherein the oxidizing gas is oxygen, air or gas containing the same.

10. The method according to claim 1, wherein the carbon source of said step (d) is continuously supplied for 1˜30 minute.

11. The method according to claim 1, wherein the oxidizing gas of said step (e) is continuously supplied for 30 second to 3 minute.

12. The method according to claim 1, wherein the method further repeats said steps (e) to (f) after said step (f).

13. A method for producing carbon nanotubes, comprising steps of: (a) providing a substrate; (b) coating a catalyst layer on said substrate; (c) heating the substrate with said catalyst layer; and (d) continuously supplying a carbon source to grow carbon nanotubes; wherein said method characterized by: supplying an oxidizing gas and interrupting the supplement of said carbon source at the same time during the period of continuously supplying said carbon source; and stopping the supplement of said oxidizing gas and resupplying said carbon source.

14. The method according to claim 13, wherein the substrate is a silicon substrate, a glass substrate, or metallic substrates.

15. The method according to claim 13, wherein the catalyst layer is coated by sputter deposition, electro-plating, or wet chemistry methods.

16. The method according to claim 13, wherein the catalyst layer is made of iron, iron-silicon alloys, or an iron-silicon alloy containing an aluminum underlayer.

17. The method according to claim 13, wherein the method further comprises an etching step before said continuously supplying a carbon source.

18. The method according to claim 13, wherein the substrate in said step (c) is heated to 370˜410° C.

19. The method according to claim 13, wherein the carbon source is methane, ethane, propane, benzene, mixture thereof or combination thereof with an equilibrium gas.

20. The method according to claim 13, wherein the equilibrium gas is hydrogen, oxygen, nitrogen, ammonia or mixture thereof.

21. The method according to claim 13, wherein the oxidizing gas is oxygen, air or gas containing the same.

22. Carbon nanotubes, which are produced by the method according to claim 1.
